(19) United States
(12) Patent Application Publication
(10) Pub. No.: US 2008/0308152 A1
(43) Pub. Date: Dec. 18, 2008

(54) SOLAR COLLECTOR WITH ANGLED COOLING FINS

(75) Inventor: ROBERT E. GRIP, Rancho Palos Verdes, CA (US)

Correspondence Address: WILDMAN HARROLD ALLEN & DIXON LLP;AND THE BOEING COMPANY, 225 W. WACKER DR., CHICAGO, IL, 60606, US

(73) Assignee: THE BOEING COMPANY, CHICAGO, IL (US)

(21) Appl. No.: 11/763,965

(22) Filed: Jun. 15, 2007

(51) Int. Cl. H01L 31/024

(52) U.S. Cl. 136/259

(57) ABSTRACT

In one embodiment, a solar collector includes a heat pipe and at least one cooling fin. The at least one cooling fin is attached to the heat pipe at a non-perpendicular first angle relative to the heat pipe. In further embodiments, methods of transferring heat are disclosed, in addition to methods of manufacturing solar collectors.

### BACKGROUND

Many solar collectors and methods of their use and manufacture exist today. These solar collectors are often used to turn solar radiation into electricity. In one existing solar collector, the solar collector may include a reflective surface, a solar cell, a heat pipe, and a plurality of cooling fins. The reflective surface, which may be a lens or shaped reflective surface, may reflect and magnify sunlight to the solar cell which may turn the solar radiation into electricity to power a device. This may allow for the most expensive part of a solar collector, the solar cell, to remain small to provide an affordable device. The magnification of the suns rays over the small solar cell may cause a substantial heat load into the solar cell. This solar collector arrangement may operate efficiently as long the solar cell does not overheat. The heat pipe may be attached to the solar cell. The cooling fins may be attached to the heat pipe at a perpendicular angle relative to the heat pipe. As the solar cell becomes hot, the excess heat may be transferred from the solar cell to the heat pipe. Fluid within the heat pipe may be heated to a vapor, the vapor may heat the interior surface of the heat pipe, the heated surface of the heat pipe may transfer heat to cooling fins, and the cooling fins may transfer heat to the ambient air around the heat pipe by means of natural convection.

However, due to the perpendicular nature of the cooling fins with respect to the heat pipe, the convective heat transfer rate from the heat pipe to the ambient air may be reduced under certain conditions. For instance, when the sun is directly overhead of the solar collector, the solar collector is parallel to a ground surface, and there is no breeze of ambient air around the heat pipe, the perpendicular configuration of the cooling fins relative to the heat pipe is not conducive to cooling of the heat pipe through convection to the ambient air. This is because the parallel alignment of the cooling fins with respect to the ground makes it more difficult for the heated ambient air to rise. In this circumstance, the solar cell may be damaged due to the heat pipe not being able to transfer sufficient excessive heat to the ambient air. Additional problems may exist with this or other types of solar collectors.

A solar collector, method of use, and/or method of manufacture is needed to decrease one or more problems associated with one or more of the existing solar collectors and/or methods.

### SUMMARY

In one aspect of the disclosure, a solar collector comprises a heat pipe and at least one cooling fin. The at least one cooling fin is attached to the heat pipe at a non-perpendicular first angle relative to the heat pipe.

In another aspect of the disclosure, a method is provided of transferring heat from a solar collector. In one step, a solar collector is provided comprising a heat pipe, at least one cooling fin, and a solar cell. The at least one cooling fin is attached to the heat pipe at a non-perpendicular first angle relative to the heat pipe. In an additional step, sun rays are reflected to the solar cell. In yet another step, excess heat is transferred from the solar cell to the heat pipe. In an additional step, heat is transferred from the heat pipe to ambient air outside of the heat pipe through convection.

In a further aspect of the disclosure, a method is provided for manufacturing a solar collector. In one step, a heat pipe and at least one cooling fin are provided. In another step, the at least one cooling fin is attached to the heat pipe at a non-perpendicular first angle relative to the heat pipe.

These and other features, aspects and advantages of the disclosure will become better understood with reference to the following drawings, description and claims.

### BRIEF DESCRIPTION OF THE DRAWINGS

FIG. 1 shows a front view of one embodiment of a solar cell apparatus for using sun rays from a directly overhead sun to create electricity;

FIG. 1A shows a view through 1A-1A of the embodiment of FIG. 1;

FIG. 1B shows a cross-sectional view through 1B-1B of the heat pipe of the embodiment of FIG. 1A;

FIG. 2 shows a left side view of the embodiment of FIG. 1;

FIG. 2A shows a view through 2A-2A of the view of FIG. 2;

FIG. 3 shows a left side view of the embodiment of FIG. 1 in another position while being subjected to different environmental conditions;

FIG. 4 shows a left side view of the embodiment of FIG. 1 in still another position while being subjected to still other environmental conditions;

FIG. 5 is a flowchart showing one embodiment of a method of transferring heat from a solar collector; and

FIG. 6 is a flowchart showing one embodiment of a method of manufacturing a solar collector.

### DETAILED DESCRIPTION

The following detailed description is of the best currently contemplated modes of carrying out the disclosure. The description is not to be taken in a limiting sense, but is made merely for the purpose of illustrating the general principles of the disclosure, since the scope of the disclosure is best defined by the appended claims.

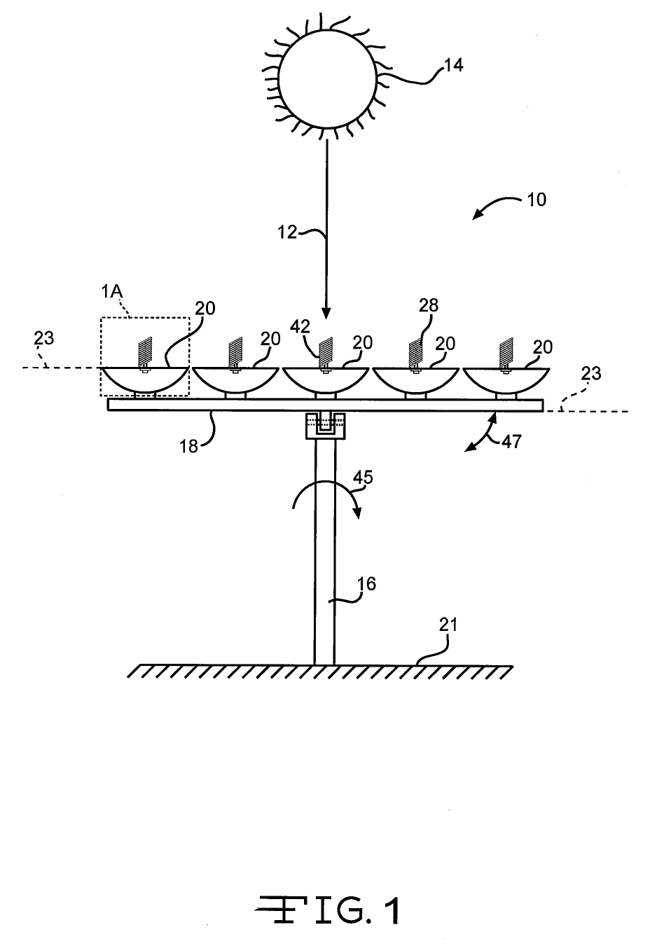

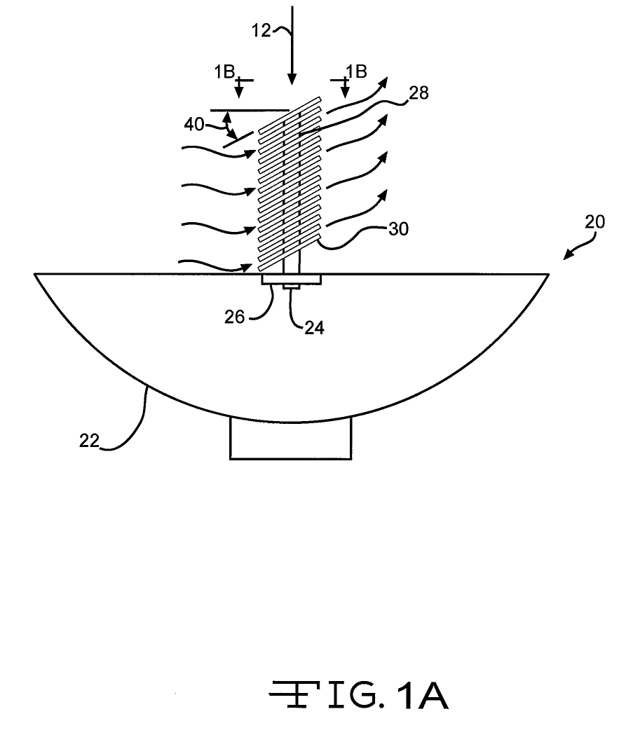

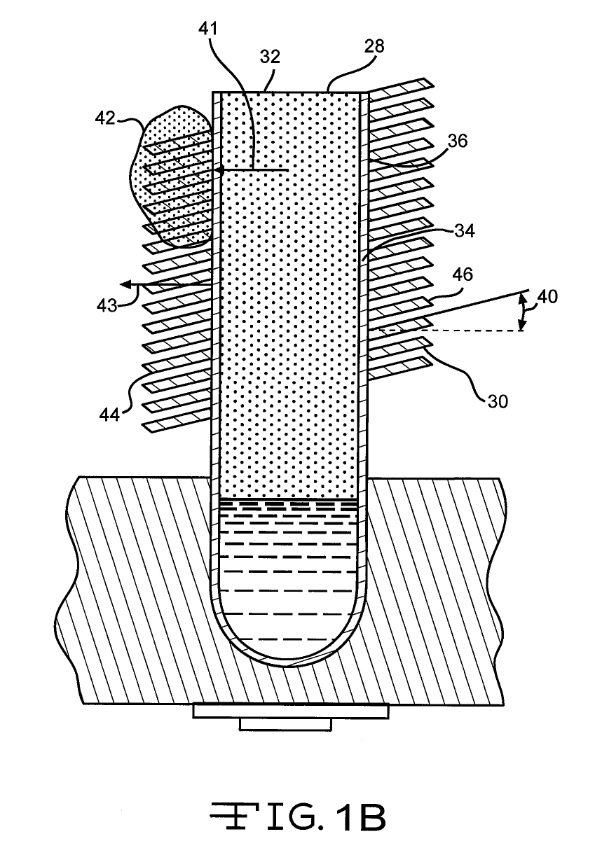

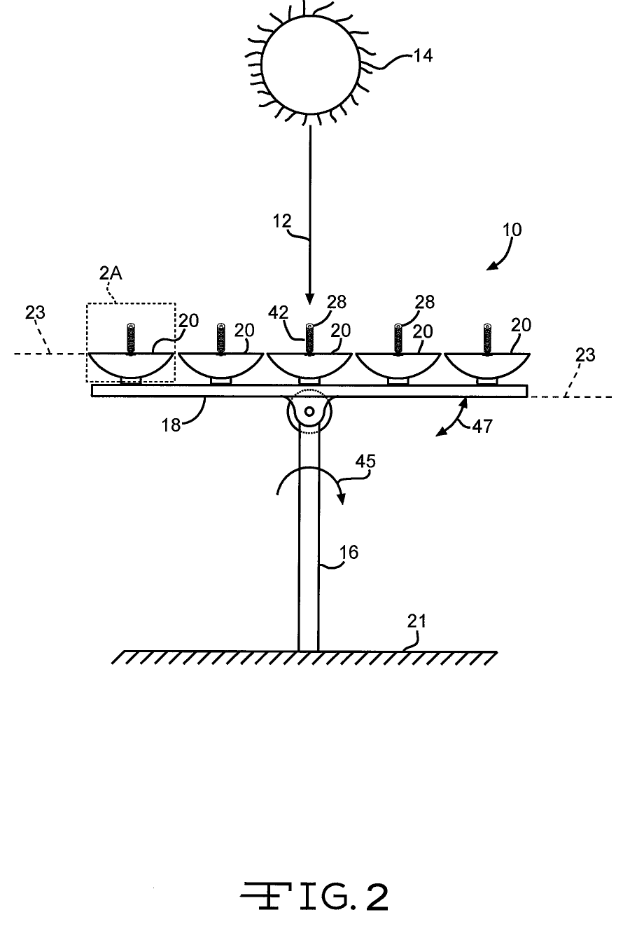

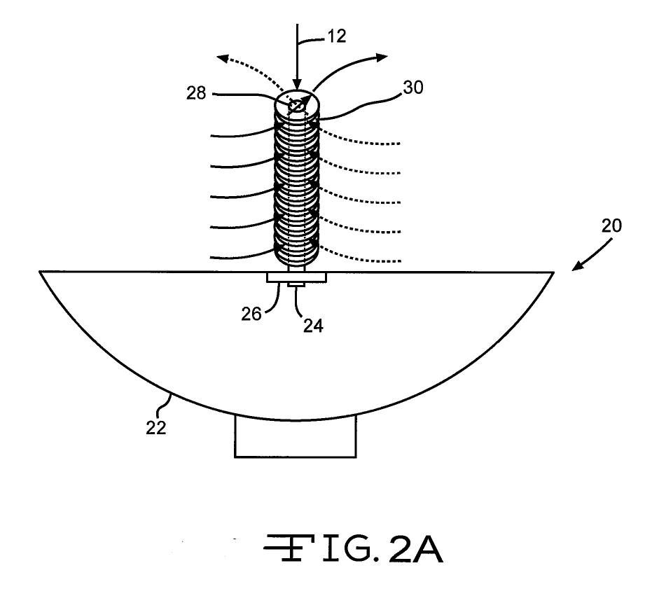

FIG. 1 shows a front view of one embodiment of a solar cell apparatus 10 for using sun rays 12 from the sun 14 to create electricity. As a further view, FIG. 2 shows a left side view of the embodiment of FIG. 1. As shown in FIGS. 1 and 2, the solar cell apparatus 10 may comprise a substantially vertical stand member 16, a support stand member 18, and a plurality of solar collectors 20. The substantially vertical stand member 16 may comprise a circular member extending in a substantially perpendicular direction to a ground surface 21. The vertical stand member 16 may be adapted to rotate with respect to the ground surface 21 in order to change the orientation and/or direction of the solar collectors 20. In other embodiments, the substantially vertical stand member 16 may be stationary, and a tracker mechanism may orient the stand member 18 and the attached plurality of solar collectors 20 to track the sun. In still other embodiments, the stand member 16 may be of other shapes, sizes, configurations, or orientations, and/or may move in a variety of directions. The support stand member 18 may comprise a rectangular member pivotally attached to the vertical stand member 16, with the solar collectors 20 attached to the support stand member 18 in a substantially parallel alignment, such as a precisely parallel alignment or an alignment being within one degree of being precisely parallel. The support stand member 18 may be adapted to pivot about the vertical stand member 16 in order to change the orientation and/or direction of the solar collectors 20.

In the embodiment shown in FIGS. 1 and 2, the angle 23 with respect to the ground surface 21 of both the support stand member 18 and the parallel-aligned solar collectors 20 is 0 degrees, the sun 14 is directly overhead of the solar collectors 20, and the ambient air 42 around the heat pipe 28 is still and not blowing. In other embodiments, the angle 23 of both the support stand member 18 and the attached the solar collectors 20 with respect to the ground surface 21 may be changed by pivoting the support stand member 18 about the vertical stand member 18, the sun 14 may be in different positions with respect to the ground 21, and/or the ambient air 42 around the heat pipe 28 may be blowing to varying degrees. It should be noted that by rotating the vertical stand member 16 with respect to the ground surface 21, and/or by tilting the support stand member 18 with respect to the ground surface 21, the solar collectors 20 may be oriented in order to place them in the ideal orientation to gather the maximum amount of sun rays 12 as the sun 14 moves through the sky throughout the day.

In order to show a close-up of one of the solar collectors 20, FIG. 1A shows a view through 1A-1A of the embodiment of FIG. 1, while FIG. 2A shows a view through 2A-2A of the view of FIG. 2. As shown in FIGS. 1A and 2A, each solar collector 20 may comprise a reflective surface 22, a solar cell 24, a base plate 26, a heat pipe 28, and a plurality of cooling fins 30. The reflective surface 22 may be curved in order to direct sun rays 12 towards the solar cell 24. The solar cell 24 may collect the sun rays 12 and use the heat from the sun rays 12 to provide electricity to one or more powered devices or power converters as part of a large-scale installation of a power utility. The solar cell 24 may be attached to a base plate 26 which is attached to the heat pipe 28. The base plate 26 may be rectangular, curved, or of other types, shapes, sizes, configurations, or orientations. The heat pipe 28 may extend substantially perpendicularly from the base plate 26.

Each of the plurality of cooling fins 30 may be attached to the heat pipe 28 at a non-perpendicular first angle 40 relative to the heat pipe 28. The cooling fins 30 may be curved, circular, elliptical, polygonal, rectangular, and/or of another type, shape, or size. Ten to twenty cooling fins 30 may be attached to each heat pipe 28. In other embodiments, any number of cooling fins 30 may be attached to each heat pipe 28. The cooling fins 30 may be made of copper, steel, or other conductive material. The non-perpendicular first angle 40 may range from 1 to 45 degrees. In one embodiment, the non-perpendicular first angle 40 may range from 1 to 10 degrees. In another embodiment, the non-perpendicular first angle 40 may range from 10 to 20 degrees. In still another embodiment, the non-perpendicular first angle 40 may range from 20 to 30 degrees. In yet another embodiment, the non-perpendicular first angle 40 may range from 30 to 45 degrees. In other embodiments, the non-perpendicular first angle 40 may comprise any angle which is not perpendicular to the heat pipe 28.

In order to limit and/or avoid damage to the solar cell 24 due to excessive heat, the solar cell 24 may be adapted to transfer excess heat to the heat pipe 28. As shown in FIG. 1B, which is a cross-sectional view through 1B-1B of the heat pipe 28 of the embodiment of FIG. 1A, the heat pipe 28 may comprise a circular pipe member having a hollow interior chamber 32 which contains a fluid 34, such as water or other fluid. The heat pipe 28 may be adapted to be heated with the excess heat of the solar cell 24 thereby vaporizing the fluid 34 within the chamber 32 of the heat pipe 28 into a vapor 36. The vapor 36 may be adapted to transfer heat from the vapor 36 to a surface 38 of the heat pipe 28 through conduction 41. The heated heat pipe 28 may be adapted to transfer heat from the heat pipe 28 to ambient air 42 outside of the heat pipe 28 through convection 43 utilizing the cooling fins 30.

The non-perpendicular first angle 40 of the cooling fins 30 may allow the rate and/or amount of convection heat transfer 43, from the heat pipe 28 to the ambient air 42, to be increased over existing cooling fins which are perpendicular to a heat pipe, due to the heated ambient air 42 being forced to flow from a low point 44 to a high point 46 in each cooling fin 30 due to the effect of heat rising. This may allow a more rapid and/or more extensive transfer of excess heat away from the solar cell 24, thereby helping to further limit and/or avoid damage to the solar cell 24 due to excessive heat. This is especially important in the embodiment of FIGS. 1 and 2 where the angle 23 with respect to the ground surface 21 of both the support stand member 18 and the parallel-aligned solar collectors 20 is 0 degrees, the sun 14 is directly overhead of the solar collectors 20, and the ambient air 42 around the heat pipe 28 is still and not blowing. Many of the existing perpendicular cooling fins would not help in cooling the heat pipe in this condition due to the uniform heights along the cooling fins, which does not allow for the heated air between the fins to rise vertically.

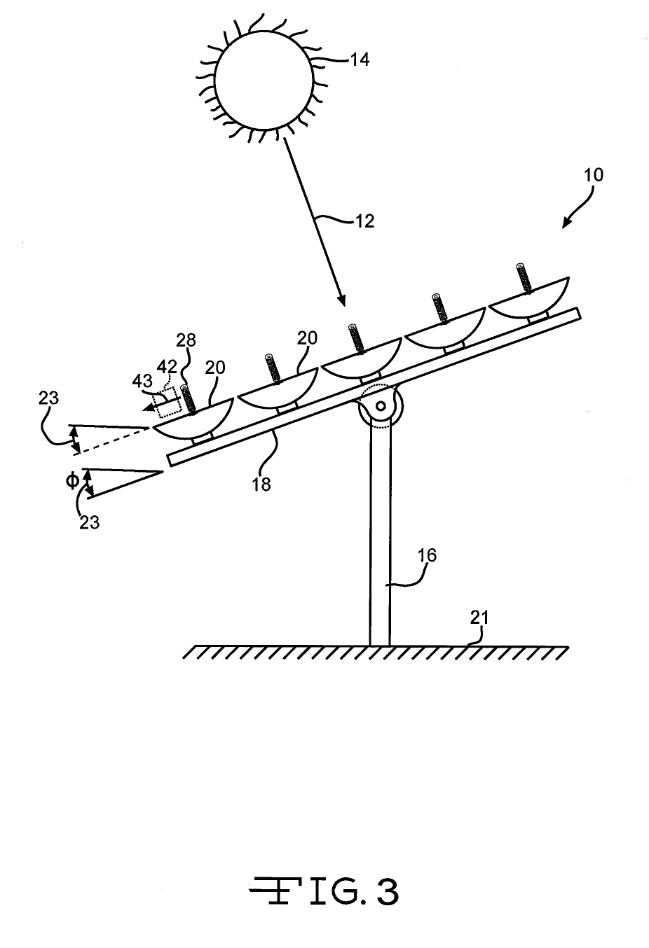

Moreover, the non-perpendicular first angle 40 of the cooling fins 30 may allow the rate and/or amount of convection heat transfer 43, from the heat pipe 28 to the ambient air 42, to be increased over existing cooling fins which are perpendicular to a heat pipe, regardless of the positions of the solar collectors 20, regardless of the position of the sun 14, and regardless of whether the ambient air 42 around the heat pipe 28 is blowing. For instance, the heat transfer 43 from the heat pipe 28 to the ambient air 42 may still be increased in the embodiment of FIG. 3, which shows a left side view of the embodiment of FIG. 1 with the angle 23 with respect to the ground surface 21 of both the support stand member 18 and the parallel-aligned solar collectors 20 being moderately inclined, the sun 14 being disposed at a moderate angle to the solar collectors 20, and the ambient air 42 around the heat pipe 28 slightly blowing.

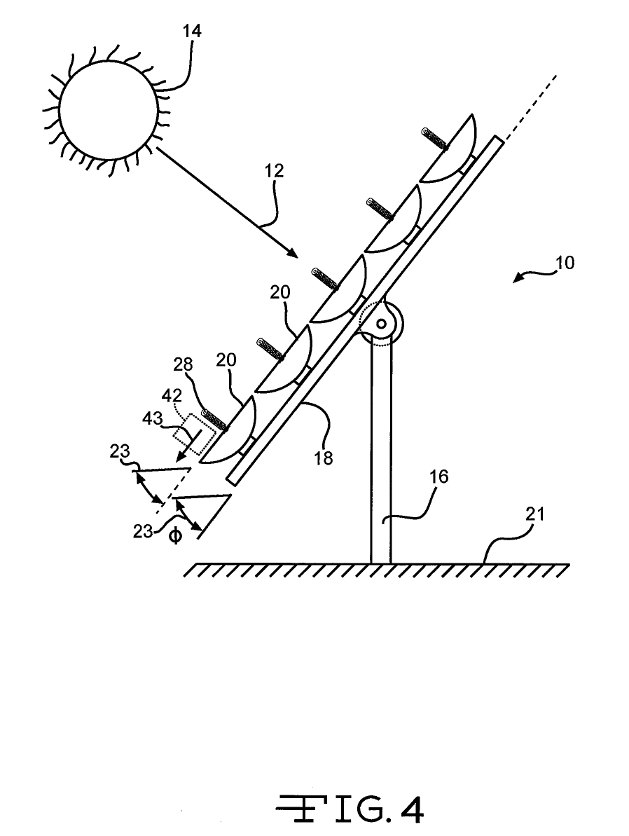

Similarly, the heat transfer 43 from the heat pipe 28 to the ambient air 42 may still be increased in the embodiment of FIG. 4, which shows a left side view of the embodiment of FIG. 1 with the angle 23 with respect to the ground surface 21 of both the support stand member 18 and the parallel-aligned solar collectors 20 being substantially inclined, the sun 14 being disposed at a substantial angle to the solar collectors 20, and the ambient air 42 around the heat pipe 28 blowing substantially.

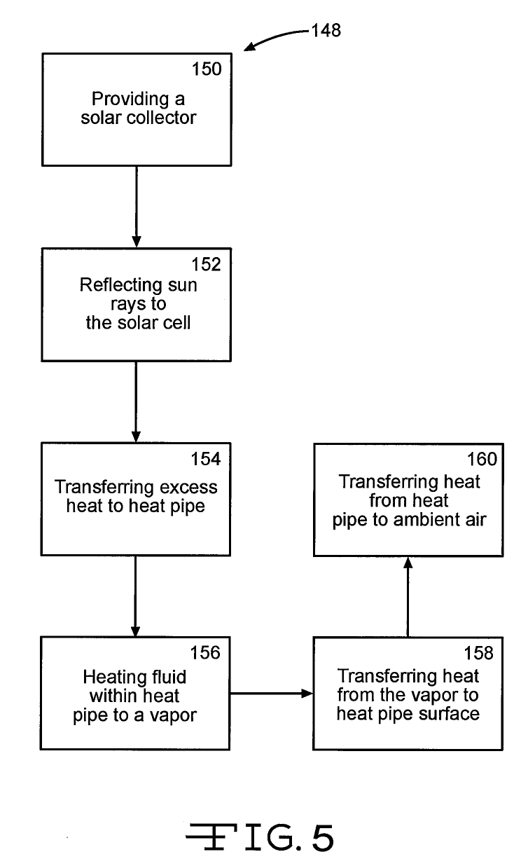

FIG. 5 shows a flowchart of an embodiment 148 of a method of transferring heat from a solar collector 20. In one step 150, a solar collector 20 may be provided comprising a heat pipe 28, at least one cooling fin 30, and a solar cell 24. The at least one cooling fin 30 may be attached to the heat pipe 28 at a non-perpendicular first angle 40 relative to the heat pipe 28. The non-perpendicular first angle 40 may be substantially in the range of 1 to 45 degrees, or in other embodiments, varying degrees. The cooling fin 30 may be curved, circular, elliptical, polygonal, rectangular, and/or of another type, shape, or size. A plurality of cooling fins 30 may be attached to the heat pipe 28. The heat pipe 28 may extend substantially perpendicularly from a base plate 26 attached to the solar cell 24.

In another step 152, sun rays 12 may be reflected to the solar cell 24. In still another step 154, excess heat from the solar cell 24 may be transferred to the heat pipe 28. In an additional step 156, fluid 34 within the heat pipe 28 may be heated to a vapor 36. In still another step 158, heat may be transferred from the vapor 36 to a surface 38 of the heat pipe 28. In an additional step 160, heat from the heat pipe 28 may be transferred to ambient air 42 outside of the heat pipe 28 through convection 43. The use of the non-perpendicular first angled cooling fin 30 may increase the amount of convection 43. During the convection process 43, the solar collector 20 may be parallel to a ground surface 21, the sun 14 may be directly overhead of the solar collector 20, and the ambient air 42 around the heat pipe 28 may not be blowing. In still other embodiments, heat may be transferred through convection 43 from the heat pipe 28 to the ambient air 42 around the heat pipe 28 regardless of the position of the solar collector 20, regardless of the position of the sun 14, and regardless of whether the ambient air 42 around the heat pipe 28 is blowing.

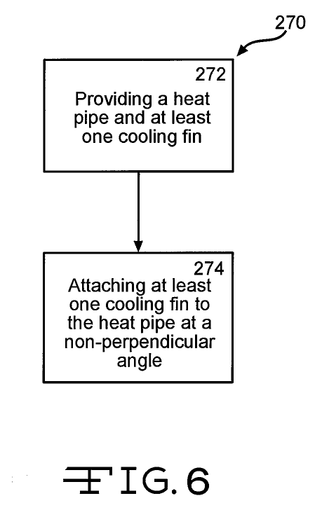

FIG. 6 shows a flowchart of an embodiment 270 of a method of manufacturing a solar collector 20. In one step 272, a heat pipe 28 and at least one cooling fin 30 are provided. In another step 274, the at least one cooling fin 30 is attached to the heat pipe 28 at a non-perpendicular first angle 40 relative to the heat pipe 28. The at least one cooling fin 30 may be curved, circular, elliptical, polygonal, rectangular, and/or of another type, shape, or size. A plurality of cooling fins 30 may be used. The non-perpendicular first angle 40 may be substantially in the range of 1 to 45 degrees, or in other embodiments, varying degrees.

One or more embodiments of the disclosure may provide one or more of the following advantages over one or more of the existing solar collectors and/or methods: increased cooling (i.e. heat transfer) of the heat pipe 28 and/or solar cell 24; reduced damage and/or costs created by excessive heating of the solar cell 24; increased convection 43 from the heat pipe 28 to the ambient air 42 around the heat pipe 28 regardless of the position of the solar collector 20, regardless of the position of the sun 14, and regardless of whether the ambient air 42 around the heat pipe 28 is blowing; and/or one or more other types of advantages over one or more of the existing solar collectors and/or methods.

It should be understood, of course, that the foregoing relates to exemplary embodiments of the disclosure and that modifications may be made without departing from the spirit and scope of the disclosure as set forth in the following claims.

1. A solar collector comprising a heat pipe and at least one cooling fin, wherein said at least one cooling fin is attached to the heat pipe at a non-perpendicular first angle relative to the heat pipe.

2. The solar collector of claim 1 wherein the heat pipe extends substantially perpendicularly from a base plate attached to a solar cell.

3. The solar collector of claim 1 wherein the heat pipe has an interior chamber which contains a fluid.

4. The solar collector of claim 3 wherein the fluid in the heat pipe is adapted to be heated into a vapor, wherein the vapor is adapted to transfer heat to a surface of the heat pipe through conduction, and wherein the heat pipe is adapted to transfer heat from the heat pipe to ambient air outside of the heat pipe through convection, wherein said convection is adapted to be increased due to the non-perpendicular first angled cooling fin.

5. The solar collector of claim 1 wherein said at least one cooling fin is adapted to cool the heat pipe through convection when the solar collector is parallel to a ground surface, a sun is directly overhead of the solar collector, and there is no ambient air breeze around the heat pipe.

6. The solar collector of claim 1 wherein there are a plurality of cooling fins attached to the heat pipe.

7. The solar collector of claim 1 wherein the at least one cooling fin is at least one of curved, circular, elliptical, polygonal, and rectangular.

8. The solar collector of claim 1 wherein the non-perpendicular first angled cooling fin forces ambient air to cool the heat pipe through convection regardless of the position of the solar collector, regardless of the position of a sun, and regardless of whether there is an ambient air breeze around the heat pipe.

9. The solar collector of claim 1 wherein said non-perpendicular first angle is substantially in the range of 1 to 45 degrees.

10. The solar collector of claim 1 wherein excess heat of a solar cell is transferred to the heat pipe.

11. The solar collector of claim 1 wherein said at least one cooling fin is at least one of copper, steel, and a conductive material.

12. The solar collector of claim 1 wherein the non-perpendicular first angled fin provides a higher convection heat transfer rate of heat from the heat pipe to ambient air than would a perpendicular first angled fin.

13. A method of transferring heat from a solar collector, the method comprising:
providing a solar collector comprising a heat pipe, at least one cooling fin, and a solar cell, wherein said at least one cooling fin is attached to the heat pipe at a non-perpendicular first angle relative to the heat pipe;
reflecting sun rays to the solar cell;
transferring excess heat from the solar cell to the heat pipe;
transferring heat from the heat pipe to ambient air outside of the heat pipe through convection.

14. The method of claim 13 wherein said convection is increased due to the non-perpendicular first angled cooling fin.

15. The method of claim 13 further comprising the steps of heating fluid in the heat pipe to a vapor, and transferring heat from the vapor to a surface of the heat pipe.

16. The method of claim 13 wherein the heat pipe extends substantially perpendicularly from a base plate attached to the solar cell.

17. The method of claim 13 wherein during said at least one transferring step using convection, the solar collector is parallel to a ground surface, a sun is directly overhead of the solar collector, and there is no ambient air breeze around the heat pipe.

18. The method of claim 13 wherein there are a plurality of cooling fins attached to the heat pipe.

19. The method of claim 13 wherein the at least one cooling fin is at least one of curved, circular, elliptical, polygonal, and rectangular.

20. The method of claim 13 wherein heat is transferred through convection from the heat pipe to ambient air outside of the heat pipe regardless of the position of the solar collector, regardless of the position of a sun, and regardless of whether there is an ambient air breeze around the heat pipe.

21. The method of claim 13 wherein said non-perpendicular first angle is substantially in the range of 1 to 45 degrees.

22. A method of manufacturing a solar collector comprising:
providing a heat pipe, and at least one cooling fin; and
attaching said at least one cooling fin to the heat pipe at a non-perpendicular first angle relative to the heat pipe.

23. The method of claim 22 wherein said non-perpendicular first angle is substantially in the range of 1 to 45 degrees.

24. The method of claim 22 wherein there are a plurality of cooling fins.

25. The method of claim 22 wherein said at least one cooling fin is at least one of curved, circular, elliptical, polygonal, and rectangular.
